(19) United States
(12) Patent Application Publication
(10) Pub. No.: US 2026/0068357 A1
(43) Pub. Date: Mar. 5, 2026

(54) PHOTODIODE AND MANUFACTURING METHOD THEREOF

(71) Applicant: Taiwan-Asia Semiconductor Corporation, Hsinchu City (TW)

(72) Inventor: Chun-Chieh Lin, Hsinchu City (TW)

(21) Appl. No.: 19/031,793

(22) Filed: Jan. 18, 2025

(30) Foreign Application Priority Data
Sep. 2, 2024 (TW) 113133028

(51) Int. Cl. H10F 77/30; H10F 30/221; H10F 71/00

(52) U.S. Cl. CPC H10F 77/337; H10F 30/221; H10F 71/121; H10F 77/306; H10F 77/334

(57) ABSTRACT

A photodiode and a manufacturing method thereof are provided. The photodiode includes a substrate, a light-active area, a filter layer and a light-shielding side wall. The light-active area is disposed on the substrate. The filter layer covers the light-active area and selectively allows only light of a specific wavelength to pass through and be received by the light-active area and generate an electrical signal correspondingly. The light-shielding sidewall completely covers the sidewall of the filter layer and the sidewall of the substrate to block any light from passing through the sidewall of the filter layer and the sidewall of the substrate and being received by the light-active area.

### CROSS-REFERENCES TO RELATED APPLICATIONS

This application claims the benefit of priority to Taiwanese Patent Application No. 113133028 filed on Sep. 2, 2024, which is hereby incorporated by reference in its entirety.

### BACKGROUND OF THE INVENTION

### Field of the Invention

The present invention relates to a photodiode and a manufacturing method thereof, in particular, to a photodiode with high linearity of photosensitivity and a manufacturing method thereof.

### Descriptions of the Related Art

A photodiode is an electronic device that converts external optical signals into electrical signals. The core function of the photodiode is to absorb and detect external optical signals and convert them into measurable electrical current. This conversion is crucial for various applications, such as optical communication, optical measurement, and image generation.

The way a photodiode absorbs external light is to utilize the semiconductor material (e.g., silicon substrate) inside the diode to absorb light. When photons enter the photodiode and are absorbed, the energy of the photons causes electrons in the valence band to jump to the conduction band for generating electron-hole pairs accordingly. These photo-generated carriers are separated by the built-in electric field in the diode and an electrical current is created accordingly.

However, in practical applications, traditional photodiodes often suffer from external light entering the device through the exposed sidewalls and causing internal interference. This interference affects the linearity of the photodiode's response and leads to computational errors in related subsequent applications. To address these issues, there is an urgent need for an innovative photodiode structure in the industry to improve the poor linearity problem of traditional photodiodes.

### SUMMARY OF THE INVENTION

The main objective of this invention is to provide an innovative photodiode and its manufacturing method. Compared to traditional photodiodes, the photodiode in this invention is equipped with light-shielding sidewalls that prevent external light from entering the interior of the device. This improves the linearity of the photodiode's sensitivity and enhances the accuracy of calculations in subsequent applications. Thereby, computational errors are reduced accordingly.

To achieve the above objective, the present invention discloses a photodiode which includes a substrate, a light-active area, a filter layer and a light-shielding side wall. The light-active area is disposed on the substrate. The filter layer covers the light-active area and selectively allows only light of a specific wavelength to pass through and be received by the light-active area and generate an electrical signal correspondingly. The light-shielding sidewall completely covers the sidewall of the filter layer and the sidewall of the substrate to block any light from passing through the sidewall of the filter layer and the sidewall of the substrate and being received by the light-active area.

In one embodiment of the photodiode of the present invention, the light-shielding sidewall comprises black epoxy resin.

In one embodiment of the photodiode of the present invention, the light of the specific wavelength is a light of a wavelength range less than 1200 nanometers (nm).

In one embodiment of the photodiode of the present invention, the filter layer is a band pass filter layer.

In one embodiment of the photodiode of the present invention, the photodiode further comprises an anti-reflective layer formed on the filter layer.

To achieve the above objective, the present invention discloses a manufacturing method of a photodiode which comprises the following steps: providing a substrate, forming a light-active area, disposed on the substrate, forming a filter layer, covering the light-active area and selectively allowing only a light of a specific wavelength to pass through and being received by the light-active area for generating an electrical signal correspondingly, and forming a light-shielding sidewall, completely covering the sidewall of the filter layer and the sidewall of the substrate to block any light from passing through the sidewall of the filter layer and the sidewall of the substrate and being received by the light-active area.

In one embodiment of the manufacturing method of the present invention, the step of forming a light-shielding sidewall is to form a sidewall made by black epoxy resin.

In one embodiment of the manufacturing method of the present invention, the step of forming a filter layer is to form a band pass filter layer.

In one embodiment of the manufacturing method of the present invention, the manufacturing method further comprises a step of forming an anti-reflective layer formed on the filter layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 illustrates a schematic diagram of a conventional photodiode;

FIG. 2 illustrates a schematic diagram of the photosensitivity linearity of a conventional photodiode under ideal and actual operating conditions;

FIG. 3 illustrates a schematic diagram of the photosensitivity linearity at various positions within the body of a conventional photodiode;

FIG. 4 illustrates a schematic diagram of a photodiode in one embodiment of the present invention; and

FIG. 5 illustrates a schematic diagram of the manufacturing process steps of the photodiode of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

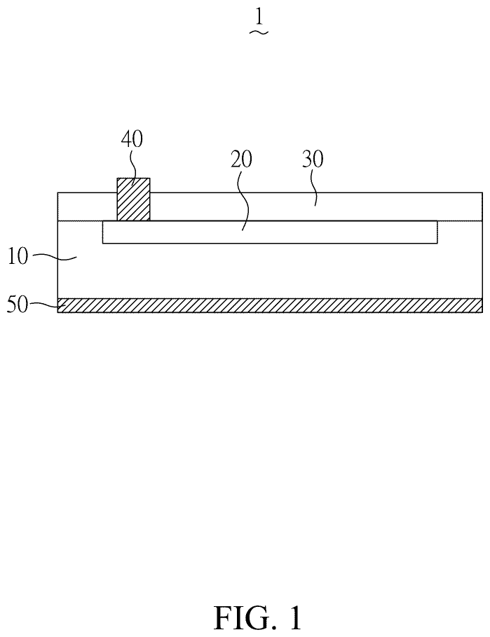

Please refer to FIG. 1, which shows a schematic diagram of a conventional photodiode. As shown, in this embodiment, the photodiode 1 comprises a substrate 10, a light-active area 20, a filter layer 30, an upper electrode 40, and a lower electrode 50. The light-active area 20 includes a silicon diode photosensitive structure disposed at the central region of the substrate 10 to detect external optical signals. Typically, the light-active area is a P/N diode photosensitive structure for receiving light of a specific wavelength. Additionally, the filter layer 30 is typically a band pass filter layer covering the light-active area 20 and selectively allows only light of a specific wavelength to pass through and be received by the light-active area 20 while blocking light of other wavelengths.

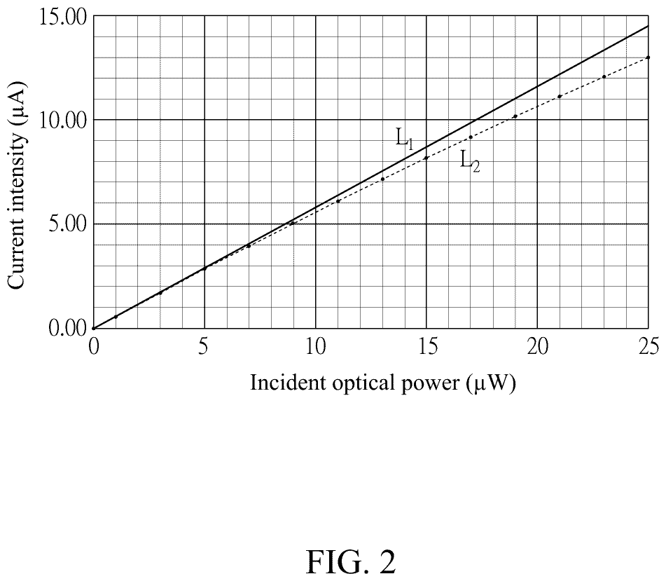

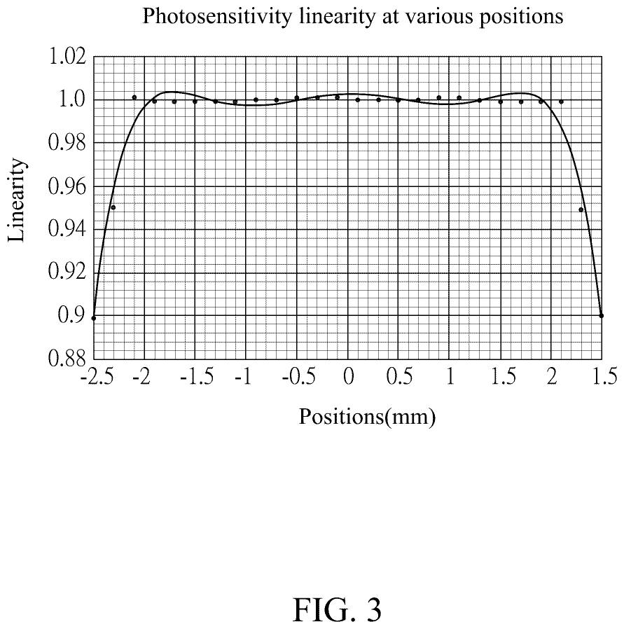

Please refer to FIG. 2 and FIG. 3, which show the photosensitivity linearity of the photodiode 1 from FIG. 1 under ideal and actual operating conditions. In FIG. 2, line L1 represents the linearity of the photodiode under ideal conditions, where the relationship between the increase in incident optical power and the corresponding generated current intensity is linear. Conversely, line L2 represents the linearity of the relationship between the incident optical power and the corresponding generated current intensity during actual operation. As shown, it is apparent that as the incident power increases, the intensity of the electrical signal generated by the photodiode does not maintain a linear increase and shows a certain degree of attenuation. Additionally, as illustrated in FIG. 3, when analyzing the photosensitivity linearity at various positions within the body of the photodiode, it is evident that the photosensitivity linearity decreases sharply at the edge regions, while the central region, excluding the edges, maintains high consistency in photosensitivity linearity.

The issue of photosensitivity linearity in the conventional photodiode 1 is primarily due to its exposed sidewalls, which consist of the exposed sidewall edges of the substrate 10 and the filter layer 30. During the actual operation of the photodiode 1, these exposed sidewalls fail to block external light and allow it to enter the device's interior and be received by the light-active area 20 for thereby causing interference and affecting photosensitivity linearity. To address this issue, it is essential to effectively prevent external light from entering the device through exposed sidewalls to improve the photosensitivity linearity of the device and reduce computational errors in subsequent calculations based on the electrical signals generated by the device.

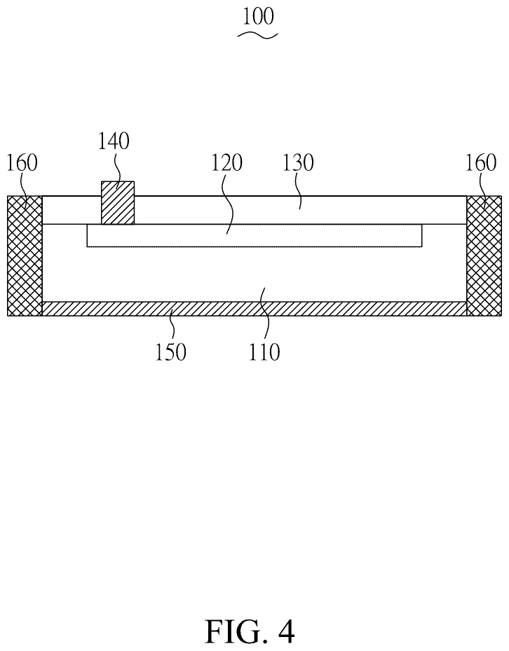

Refer to FIG. 4, which shows a photodiode 100 in an embodiment of the present invention. The photodiode 100 includes a substrate 110, a light-active area 120, a filter layer 130, an upper electrode 140, a lower electrode 150, and a light-shielding sidewall 160. The substrate 110 serves as the base supporting material of the photodiode 100 and is typically made of an optically transparent material to allow light to pass through. Materials with good light transmittance, such as silicon or quartz, are generally chosen for the substrate 110. In this embodiment, an N-type doped silicon substrate 110 is used as the substrate material. The thickness of the substrate 110 can be adjusted according to specific application and design requirements, typically ranging from several hundred micrometers (μm) to a few millimeters (mm). The light-active area 120 of the photodiode 100 contains a silicon diode photosensitive structure disposed at the central region of the substrate 110 for detecting external optical signals, and is typically a P/N diode photosensitive structure that generates a corresponding electrical signal upon receiving light of a specific wavelength.

The filter layer 130 is typically a band pass filter layer that covers the light-active area 120 for selectively allowing only light of a specific wavelength to pass through and being received by the light-active area 120, while blocking light of other wavelengths. In one embodiment of the present invention, the filter layer 130 allows only light with a wavelength below approximately 1200 nanometers (nm) to pass, while blocking longer wavelengths, such as infrared light with wavelengths above 1200 nm, from being absorbed by the light-active area 120. In a preferred embodiment, the filter layer 130 is a multi-layer optical film structure. Additionally, the photodiode 100 of the present invention may further include an anti-reflective layer (not shown) formed on top of the filter layer 130 to reduce external light reflection and increase the light absorption rate of the photodiode. The upper electrode 140 is disposed on the filter layer 130, while the lower electrode 150 is disposed on the backside of the substrate 110. The electrodes are used to apply an electric field to control the optical characteristics of the filter layer 130. By adjusting the voltage, the refractive index of the dielectric layer within the filter layer 130 structure can be modified for allowing adjustment of the filter's center wavelength or bandwidth.

A distinguishing feature of the photodiode 100 in the present invention is that it further includes a light-shielding sidewall 160, which completely covers the sidewalls of the filter layer 130 and the substrate 110. This configuration blocks any light from passing through the sidewalls of the filter layer 130 and substrate 110 and being received by the light-active area 120, and thereby, interference from side light to the light-active area 120 is reduced. This improves the photosensitivity linearity of the device and minimizes subsequent computational errors. In a specific embodiment, the light-shielding sidewall 160 is made of, such as, but not limited to, black epoxy resin. Any materials capable of effectively blocking light from entering the interior of the photodiode may be used for the light-shielding sidewall of the photodiode in the present invention.

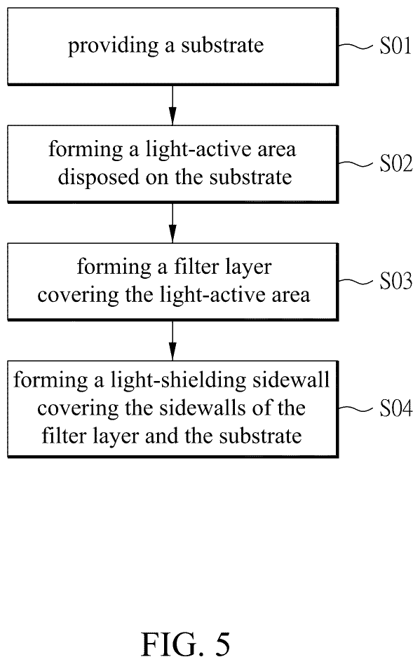

Refer to FIG. 5, which illustrates the manufacturing steps of the photodiode in the present invention. First, in step S01, a substrate is provided. Next, in step S02, a light-active area is formed on the substrate. In step S03, a filter layer is formed for covering the light-active area. This layer selectively allows only light of a specific wavelength to pass through and be received by the light-active area for generating a corresponding electrical signal. Finally, in step S04, a light-shielding sidewall is formed to completely cover the sidewalls of the filter layer and substrate for thereby blocking any light from passing through these sidewalls and being received by the light-active area. Descriptions of the relevant components can be referred to in the previous sections and are not reiterated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A photodiode, comprising:
a substrate;
a light-active area, disposed on the substrate;
a filter layer, covering the light-active area and selectively allowing only a light of a specific wavelength to pass through and being received by the light-active area for generating an electrical signal correspondingly; and
a light-shielding sidewall, completely covering the sidewall of the filter layer and the sidewall of the substrate to block any light from passing through the sidewall of the filter layer and the sidewall of the substrate and being received by the light-active area.

2. The photodiode of claim 1, wherein the light-shielding sidewall comprises black epoxy resin.

3. The photodiode of claim 1, wherein the light of the specific wavelength is a light of a wavelength range less than 1200 nanometers (nm).

4. The photodiode of claim 1, wherein the filter layer is a band pass filter layer.

5. The photodiode of claim 4, further comprising an anti-reflective layer formed on the filter layer.

6. A manufacturing method of a photodiode, comprising:
providing a substrate;
forming a light-active area, disposed on the substrate;
forming a filter layer, covering the light-active area and selectively allowing only a light of a specific wavelength to pass through and being received by the light-active area for generating an electrical signal correspondingly; and
forming a light-shielding sidewall, completely covering the sidewall of the filter layer and the sidewall of the substrate to block any light from passing through the sidewall of the filter layer and the sidewall of the substrate and being received by the light-active area.

7. The manufacturing method of claim 6, wherein the step of forming a light-shielding sidewall is to form a sidewall made by black epoxy resin.

8. The manufacturing method of claim 6, wherein the light of the specific wavelength is a light of a wavelength range less than 1200 nanometers (nm).

9. The manufacturing method of claim 6, wherein the step of forming a filter layer is to form a band pass filter layer.

10. The manufacturing method of claim 9, further comprising a step of forming an anti-reflective layer formed on the filter layer.
